(19) United States
(12) Patent Application Publication
(10) Pub. No.: US 2025/0369109 A1
(43) Pub. Date: Dec. 4, 2025

(54) FILM FORMING METHOD AND FILM FORMING APPARATUS

(71) Applicant: Tokyo Electron Limited, Tokyo (JP)

(72) Inventors: Tsuyoshi TAKAHASHI, Nirasaki City (JP); Akinobu KAKIMOTO, Nirasaki City (JP); Kensuke HIGUCHI, Nirasaki City (JP); Yoshikazu IDENO, Nirasaki City (JP); Masaki SANO, Nirasaki City (JP)

(21) Appl. No.: 19/298,418

(22) Filed: Aug. 13, 2025

Related U.S. Application Data
(63) Continuation of application No. PCT/JP2024/003852, filed on Feb. 6, 2024.

(30) Foreign Application Priority Data
Feb. 20, 2023 (JP) 2023-023927

(51) Int. Cl. C23C 16/455; C23C 16/34; C23C 16/44; C23C 16/46; C23C 16/52; H01L 21/285; H01L 21/3205

(52) U.S. Cl. CPC C23C 16/45527; C23C 16/34; C23C 16/4408; C23C 16/45544; C23C 16/45553; C23C 16/45565; C23C 16/4557; C23C 16/46; C23C 16/52; H01L 21/28506; H01L 21/32051

(57) ABSTRACT

A film forming method includes: providing a substrate in a processing container; forming a titanium nitride film on the substrate by an ALD method by supplying a titanium-containing raw material gas and a nitrogen-containing reactant gas into the processing container; and incorporating nickel into the titanium nitride film during the forming the titanium nitride film.

### CROSS-REFERENCE TO RELATED APPLICATION

The application is a Bypass Continuation Application of PCT International Application No. PCT/JP2024/003852, filed on Feb. 6, 2024 and designating the United States, the international application being based upon and claiming the benefit of priority from Japanese Patent Application No. 2023-023927, filed on Feb. 20, 2023, the entire content of which is incorporated herein by reference.

### TECHNICAL FIELD

The present disclosure relates to a film forming method and a film forming apparatus.

### BACKGROUND

In a manufacturing process of semiconductor devices, titanium nitride (TiN) films are used for various purposes such as electrodes (e.g., lower electrodes of DRAM) and barrier films. General thin film formation techniques are employed for forming the TiN films. Patent Document 1 discloses forming a TiN film by an atomic layer deposition (ALD) method using TiCl₄ gas and NH₃ gas.

### Prior Art Document

### Patent Document

Patent Document 1: Japanese Patent Laid-open Publication No. 2018-66050

### SUMMARY

A film forming method according to one embodiment of the present disclosure includes: providing a substrate in a processing container, forming a titanium nitride film on the substrate by an ALD method by supplying a titanium-containing raw material gas and a nitrogen-containing reactant gas into the processing container, and incorporating nickel into the titanium nitride film during the forming the titanium nitride film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating an example of a film forming apparatus for use in performing a film forming method according to a first embodiment.

FIG. 2 is a flowchart illustrating an example of the film forming method according to the first embodiment.

FIG. 3 is a diagram illustrating an example of a gas supply sequence when forming a TiN film by an ALD method.

FIG. 4 is a diagram illustrating a relationship between a thickness and a specific resistance of a TiN film, which is formed by ALD while varying a showerhead temperature in a range between 200 degrees C. and 450 degrees C.

FIG. 5 is a diagram illustrating a relationship between a thickness and a specific resistance of a TiN film, which is formed with a Ni concentration of approximately 0 at % and with a Ni concentration of approximately 4 at %.

FIG. 6 is a diagram illustrating a relationship between a Ni concentration measured by RBS and a specific resistance of a TiN film, which is formed while varying the Ni concentration in the film by a showerhead temperature and the like.

FIG. 7 is a diagram illustrating a concentration distribution of Cl in a TiN film, which is formed by ALD while varying a showerhead temperature in a range between 200 degrees C. and 450 degrees C.

FIG. 8 is a diagram illustrating a relationship between a Ni concentration measured by RBS and a Cl concentration measured by SIMS in a TiN film.

FIG. 9 is a diagram illustrating a relationship between a Ni concentration and a grain size of a TiN film.

FIG. 10 is a diagram illustrating a relationship between a Ni concentration measured by XPS and a sheet resistance Rs [ohms/sq] of a TiN film, which is formed while varying the Ni concentration in the TiN film.

FIG. 11 is a cross-sectional view illustrating an example of a film forming apparatus for use in performing a film forming method according to a second embodiment.

FIG. 12 is a flowchart illustrating an example of the film forming method according to the second embodiment.

FIG. 13 is a diagram illustrating an example of a gas supply sequence in an ALD cycle in which an operation of supplying a Ni raw material gas is introduced into step ST12.

FIG. 14 is a diagram illustrating another example of a gas supply sequence in an ALD cycle in which an operation of supplying a Ni raw material gas is introduced into step ST12.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments will be described with reference to the accompanying drawings.

### Overview

First, an overview will be described.

TiN films have been used as barrier films for W or Cu wiring. However, in recent, using TiN films as embedded wiring has been studied. For the reason described above, there is a demand for a further reduction in resistance of TiN films.

Therefore, one embodiment provides a film forming method including a process of providing a substrate in a processing container, a process of forming a titanium nitride (TiN) film on the substrate by an ALD method by supplying a titanium (Ti)-containing raw material gas and a nitrogen (N)-containing reactant gas into the processing container, and a process of incorporating nickel (Ni) into the TiN film during formation of the TiN film.

By incorporating nickel (Ni) into the TiN film during formation of the TiN film, a resistance of the TiN film can be reduced, as will be described below.

A specific resistance of a TiN film increases when elements that increase a resistance enter the film or when a grain size (crystal grain size) of TiN is small. Ni is an element that easily enters N-sites of TiN and easily precipitates at grain boundaries of TiN, and does not increase a specific resistance of TiN or inhibit crystal growth. Thus, Ni preferentially precipitates at N-sites and grain boundaries, which suppresses elements that increase a resistance from entering the N-sites or grain boundaries of TiN and suppresses elements that inhibit crystal growth from precipitating at the grain boundaries. Therefore, the resistance of the TiN film can be reduced.

The Ti-containing raw material gas is not particularly limited, but a gas containing Ti and chlorine (Cl) such as TiCl₄ gas is exemplified. As the gas containing Ti and Cl, TiCl₃ gas or TiCl₂ gas may also be used. The Ti-containing raw material gas may be a gas that does not contain Cl, such as tetrakis (dimethylamino) titanium (TDMAT) or tetrakis (diethylamino) titanium (TDEAT). The N-containing reactant gas is also not particularly limited, but ammonia (NH₃) gas is exemplified. As the N-containing reactant gas, hydrazine gas or a hydrazine compound gas may also be used.

A Ni concentration in the TiN film may be in a range of 2 at % to 10 at %, and further may be in a range of 2.5 at % to 5 at %.

### First Embodiment

Next, a first embodiment as a specific embodiment will be described.

In the first embodiment, as a Ni-containing member, a showerhead is provided in a processing container of a film forming apparatus, and a gas containing Ti and Cl, which is a Ti-containing raw material gas, and a N-containing reactant gas are brought into contact with the showerhead, so that Ni in the showerhead is incorporated into a TiN film.

### Film Forming Apparatus

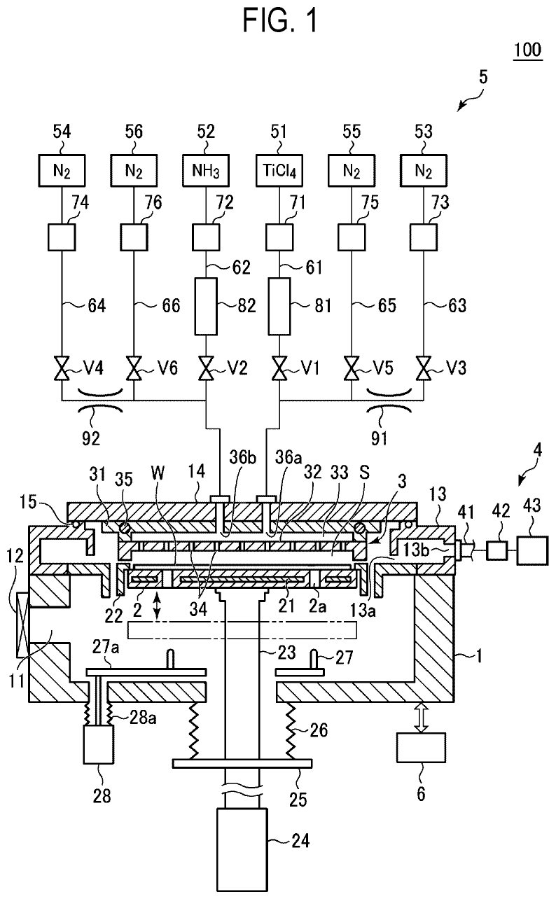

FIG. 1 is a cross-sectional view illustrating an example of a film forming apparatus for use in performing a film forming method according to a first embodiment.

As illustrated in FIG. 1, a film forming apparatus 100 includes a processing container 1, a stage 2, a showerhead 3, an exhauster 4, a gas supply mechanism 5, and a controller 6, and forms a TiN film on a substrate W by ALD film formation to be described later. The substrate W is not particularly limited, but may be, for example, a semiconductor substrate such as a Si substrate.

The processing container 1 is made of a metal such as aluminum, and has a substantially cylindrical shape. A load/unload port 11 for loading and unloading the substrate W is formed in a sidewall of the processing container 1. The load/unload port 11 can be opened or closed by a gate valve 12. An annular exhaust duct 13 having a rectangular cross section is provided on a main body of the processing container 1. A slit 13a is formed along an inner circumferential surface of the exhaust duct 13. Further, an exhaust port 13b is formed in an outer wall of the exhaust duct 13. A ceiling wall 14 is provided on an upper surface of the exhaust duct 13 to close an upper opening of the processing container 1. A gap between the ceiling wall 14 and the exhaust duct 13 is sealed airtight by a seal ring 15.

The stage 2 places the substrate W horizontally thereon, and has a disk shape having a size corresponding to the substrate W. The stage 2 is supported by a support 23. The stage 2 is made of a ceramic material such as aluminum nitride (AlN) or a metallic material such as aluminum or a nickel-based alloy. A heater 21 for heating the substrate W is embedded in the stage 2. A cover 22 is provided in the stage 2 to cover a side surface of the stage 2.

The support 23 that supports the stage 2 extends from a bottom center of the stage 2 to below the processing container 1 via a hole formed in a bottom wall of the processing container 1, and a lower end of the support 23 is connected to a lifting mechanism 24. By the lifting mechanism 24, the stage 2 can move vertically between a processing position illustrated in FIG. 1 and a transfer position, which is a position for substrate transfer and indicated by a one-dot dashed line below the processing position, via the support 23. Further, a flange 25 is attached to the support 23 at a position below the processing container 1, and a bellows 26 is provided between a bottom surface of the processing container 1 and the flange 25 to partition an atmosphere in the processing container 1 from the outside air. The bellows 26 extends and contracts according to the vertical movement of the stage 2.

Three (only two are illustrated) substrate support pins 27 are provided in a vicinity of the bottom surface of the processing container 1 to protrude upward from a lifting plate 27a. The substrate support pins 27 are movable vertically via the lifting plate 27a by a lifting mechanism 28 provided below the processing container 1, and can protrude and retract with respect to an upper surface of the stage 2 by being inserted into and passing through through-holes 2a formed in the stage 2 at the transfer position. By moving the substrate support pins 27 vertically as described above, the substrate W is delivered between a substrate transfer mechanism (not illustrated) and the stage 2. A bellows 28a is provided between the bottom surface of the processing container 1 and the lifting mechanism 28.

The showerhead 3 supplies a processing gas in the form of a shower into the processing container 1, and is formed as a Ni-containing member such as a Ni alloy. The showerhead 3 is provided to face the stage 2, and has approximately the same diameter as the stage 2. The showerhead 3 includes a main body 31 fixed to the ceiling wall 14 of the processing container 1, and a shower plate 32 connected to a lower side of the main body 31. A heater 35 for heating the showerhead 3 is embedded in the main body 31. A gas diffusion space 33 is defined between the main body 31 and the shower plate 32, and gas introduction holes 36a and 36b, which pass through a center of the main body 31 and the ceiling wall 14 of the processing container 1, are connected to the gas diffusion space 33. Gas discharge holes 34 are formed in the shower plate 32. In a state in which the stage 2 is located at the processing position, a processing space S is defined between the stage 2 and the shower plate 32.

The exhauster 4 includes an exhaust pipe 41 connected to the exhaust port 13b of the exhaust duct 13, an automatic pressure control (APC) valve 42 connected to the exhaust pipe 41, and an exhaust mechanism 43 having a vacuum pump. During processing, a gas in the processing container 1 reaches the exhaust duct 13 via the slit 13a, and is discharged from the exhaust duct 13 via the exhaust pipe 41 by the exhaust mechanism 43 of the exhauster 4.

The gas supply mechanism 5 supplies gases for use in film formation to the showerhead 3, and supplies a titanium (Ti)-containing raw material gas, a nitrogen (N)-containing reactant gas, and a purge gas or a carrier gas. The first embodiment describes an example in which TiCl₄ gas, which is a gas containing Ti and chlorine (Cl), is used as the Ti-containing raw material gas, NH₃ gas is used as the N-containing reactant gas, and N₂ gas is used as the purge gas or the carrier gas. Other inert gases such as Ar gas may also be used as the purge gas or the carrier gas.

The gas supply mechanism 5 includes a TiCl₄ gas source 51 that supplies TiCl₄ gas, an NH₃ gas source 52 that supplies NH₃ gas, and first to fourth N₂ gas sources 53, 54, 55, and 56 that supply N₂ gas.

A TiCl₄ gas line 61 is connected to the TiCl₄ gas source 51, and a valve V1, a gas storage tank 81, and a flow rate controller 71 are attached in the TiCl₄ gas line 61 in this order from downstream. An NH₃ gas line 62 is connected to the NH₃ gas source 52, and a valve V2, a gas storage tank 82, and a flow rate controller 72 are attached in the NH₃ gas line 62 in this order from downstream. First to fourth N₂ gas lines 63, 64, 65, and 66 are connected to the first to fourth N₂ gas sources 53, 54, 55, and 56, respectively. In the first to fourth N₂ gas lines 63, 64, 65, and 66, valves V3, V4, V5, and V6 are attached on downstream sides, respectively, and flow rate controllers 73, 74, 75, and 76 are attached on upstream sides, respectively.

The first N₂ gas line 63 is connected to a downstream side of the valve V1 in the TiCl₄ gas line 61, and the second N₂ gas line 64 is connected to a downstream side of the valve V2 in the NH₃ gas line 62. Further, the N₂ gas supplied from the first N₂ gas source 53 via the N₂ gas line 63 functions as a purge gas and as a carrier gas for the TiCl₄ gas. Further, the N₂ gas supplied from the second N₂ gas source 54 via the second N₂ gas line 64 functions as a purge gas and as a carrier gas for the NH₃ gas. The N₂ gas is continuously supplied from the first and second N₂ gas sources 53 and 54 during film formation.

On the other hand, the third N₂ gas line 65 and the fourth N₂ gas line 66 join the first N₂gas line 63 and the second N₂ gas line 64 on downstream sides of the valve V3 and the valve V4, respectively, and reach the TiCl₄ gas line 61 and the NH₃ gas line 62, respectively. Further, the N₂ gas supplied from the third and fourth N₂ gas sources 55 and 56 via the third and fourth N₂ gas lines 65 and 66, respectively, is used only in a purge step of ALD film formation to be described later. The TiCl₄ gas line 61 and the NH₃ gas line 62 are connected to the gas introduction holes 36a and 36b of the showerhead 3, respectively. In addition, orifices 91 and 92 for preventing backflows of the N₂ gas from the third N₂ gas line 65 and the fourth N₂ gas line 66 are provided on the downstream side of the valve V3 in the first N₂ gas line 63 and on the downstream side of the valve V4 in the second N₂ gas line 64, respectively.

Each of the flow rate controllers 71, 72, 73, 74, 75, and 76 is configured by, for example, a mass flow controller, and adjusts and controls a flow rate of a gas flowing through a corresponding gas line.

Each of the valves V1 to V6 is configured by an on-off valve that opens and closes a corresponding gas line, and performs supply and cutoff of a gas in the gas line. The valves V1 to V6 may be configured by high-speed valves capable of being opened and closed rapidly to supply and cutoff gases rapidly during ALD film formation.

The gas storage tanks 81 and 82 temporarily store the TiCl₄ gas and the NH₃ gas, respectively, before supplying the gases into the processing container 1. By storing the gases, an interior of each tank is pressurized to a predetermined pressure, and then each gas may be discharged into the processing container 1. Thus, it is possible to stably supply large flow rates of gases to the processing container. Supply and cutoff of the gases from the gas storage tanks 81 and 82 to the processing container 1 are performed by opening and closing the corresponding valves V1 and V2, respectively.

Gas storage tanks may also be provided in the third N₂ gas line 65 and the fourth N₂ gas line 66 to supply a large flow rate of N₂ gas as a purge gas when purging the processing container 1. Further, when the purging is performed sufficiently by the N₂ gas supplied from the first and second N₂ gas lines 63 and 64, the third N₂ gas line 65 and the fourth N₂ gas line 66 may not be provided. Furthermore, the gas storage tanks 81 and 82 in the TiCl₄ gas line 61 and the NH₃ gas line 62 may not be provided.

The controller 6 is configured by a computer, and includes a main controller having a CPU, an input device (e.g., a keyboard and a mouse), an output device (e.g., a printer), a display device (e.g., a display), and a storage device (storage medium). The main controller controls, for example, the valves V1 to V6, the flow rate controllers 71 to 76, the automatic pressure control valve 42, the heaters 21 and 35, the lifting mechanisms 24 and 28, and the like. Control operations for those described above by the main controller are executed based on a processing recipe, which is a control program stored in a storage medium (such as a hard disk, an optical disk, or a semiconductor memory) incorporated in the storage device.

### Film Forming Method

Next, an example of a film forming method performed using the film forming apparatus 100 configured as described above will be described.

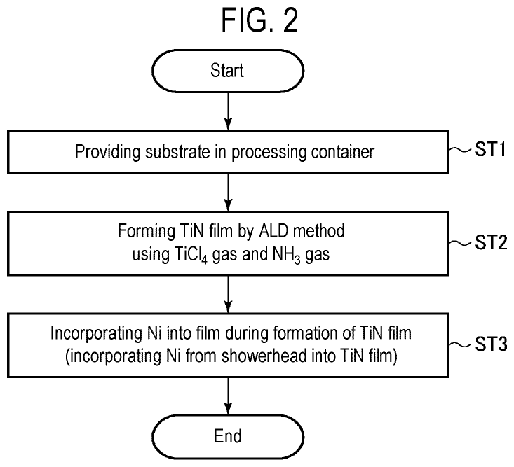

FIG. 2 is a flowchart illustrating an example of a film forming method according to the first embodiment. First, the substrate W is provided in the processing container 1 to set a state in which film formation can be performed (step ST1).

Specifically, the gate valve 12 is opened, and the substrate W is loaded from the load/unload port 11 and is placed on the stage 2. Thereafter, the gate valve 12 is closed, and the stage 2 is moved up to the processing position. At this time, a temperature of the stage 2 is set in advance to, for example, 300 degrees C. to 600 degrees C. by the heater 21, and a temperature of the showerhead 3 is set in advance to 150 degrees C. to 600 degrees C. by the heater 35. In this state, the interior of the processing container 1 is evacuated, and while the valves V3, V4, V5, and V6 are opened to introduce N₂ gas from the gas supply mechanism 5 at a preset flow rate, an open degree of the automatic pressure control valve 42 is adjusted to regulate the internal pressure of the processing container 1 to, for example, 133.3 to 2666.4 Pa.

Subsequently, in a state in which the temperature of the stage 2 (substrate temperature) is maintained to be a temperature within a range of 300 degrees C. to 600 degrees C., a TiN film is formed by an ALD method using TiCl₄ gas, which is a Ti-containing raw material gas and contains Ti and Cl, and NH₃ gas as a N-containing reactant gas (step ST2).

Here, with the valves V3 and V4 kept open to continuously supply N₂ gas from the first and second N₂ gas lines 63 and 64, the valves V1 and V2 are operated to form the TiN film by an ALD method.

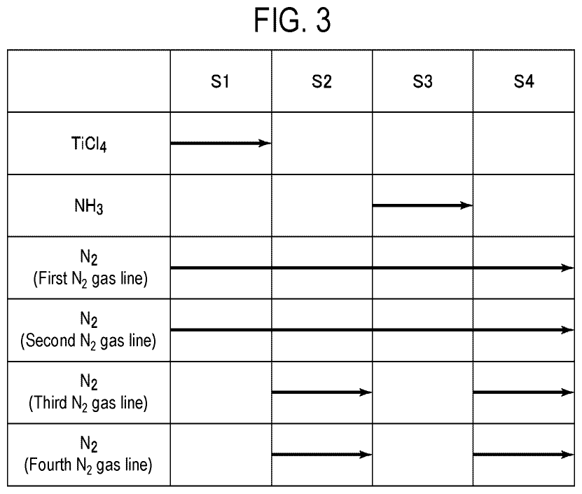

FIG. 3 is a diagram illustrating an example of a gas supply sequence at this time. In an initial state, only the valves V3 and V4 are open, and the valves V1, V2, V5, and V6 are closed. In this state, the valve V1 is first opened to supply the TiCl₄ gas from the TiCl₄ gas line 61 into the processing space S (operation S1). Thus, the TiCl₄ gas is adsorbed to a surface of the substrate W. Subsequently, the valve V1 is closed, and only the N₂ gas is supplied into the processing space S to perform purging to remove residual gases on the substrate W (operation S2). At this time, as illustrated, the valves V5 and V6 may be opened to supply the N₂ gas as a purge gas from the third and fourth N₂ gas lines 65 and 66 to enhance the purging. Subsequently, the valves V5 and V6 are closed, and the valve V2 is opened to supply the NH₃ gas from the NH₃ gas line 62 into the processing space S (operation S3). Thus, the TiCl₄ gas adsorbed to the surface of the substrate W reacts with the NH₃ gas, and a thin unit TiN film is formed. Subsequently, the valve V2 is closed, and only the N₂ gas is supplied into the processing space S to perform purging to remove residual gases on the substrate W (operation S4). At this time, similarly to operation S2, the valves V5 and V6 may be opened to supply the N₂ gas as a purge gas from the third and fourth N₂ gas lines 65 and 66 to enhance the purging. A sequence of operations S1 to S4 described above is performed a predetermined number of times. Thus, a TiN film with a desired film thickness is formed. At this time, one cycle of ALD (ALD cycle) may take 0.1 to 20 seconds.

During the TiN film formation by the ALD method in step ST2 described above, Ni is incorporated into the film (step ST3). By incorporating Ni into the TiN film, a resistance of the TiN film can be reduced as described above.

Details will be described below.

As described above, Ni is an element that easily enters N-sites of TiN and easily precipitates at grain boundaries of TiN, and does not increase a specific resistance of TiN or inhibit crystal growth. Therefore, Ni preferentially precipitates at the N-sites and the grain boundaries, which suppresses elements that increase a resistance from entering into the N-sites and the grain boundaries of TiN and suppresses elements that inhibit crystal growth from precipitating at the grain boundaries. Thus, a resistance of the TiN film can be reduced.

In particular, when TiCl₄ gas, which is a gas containing Ti and Cl, is used as the Ti raw material gas as in the present embodiment, the specific resistance of the TiN film obtained by the film formation increases as a concentration of Cl, which is derived from the raw material gas, in the film increases. Further, growth of crystal grains is inhibited by the Cl in the film, which also increases the specific resistance of the TiN film. Therefore, when a gas containing Ti and Cl is used as the Ti raw material gas as in the present embodiment, it is important to reduce the Cl concentration in the film in order to reduce the resistance of the TiN film.

The Cl concentration in the film can be reduced by setting the substrate temperature to be a high temperature (e.g., 500 degrees C. or higher) to promote a film forming reaction, which results in reduction in the resistance of the TiN film to a certain extent.

However, there may be cases where the substrate temperature cannot be raised to 400 degrees C. or higher due to constraints in device process. In such cases, the Cl concentration in the film cannot be reduced sufficiently. Further, even when the substrate temperature is set to be higher than 600 degrees C., it is difficult to reduce the specific resistance significantly from 100 micro-ohms centimeters with a film thickness of 10 nm. Thus, setting the substrate temperature to be such a high temperature cannot be a countermeasure against cases requiring further reduction in resistance.

Accordingly, when a gas containing Ti and Cl is used as the Ti raw material gas, by incorporating Ni into the film in step ST3, it is possible to reduce the resistance of the TiN film through the following mechanisms (a) and (b) based on the above-described characteristics of Ni.
(a) Although Cl enters N-sites in a TiN crystal lattice, Ni enters the N-sites more easily than Cl. Therefore, by incorporating Ni, Ni preferentially enters the N-sites and the Cl concentration in the film can be reduced.
(b) Although Cl also precipitates at grain boundaries of TiN crystals and inhibits growth of the TiN crystals, Ni precipitates along the grain boundaries more readily than Cl. Thus, by incorporating Ni into the TiN film, Ni preferentially precipitates at the grain boundaries.

Therefore, Cl, which inhibits growth of TiN crystals, is suppressed from precipitating at the grain boundaries, and the grain size can be increased.

In the present embodiment, step ST3 is performed by incorporating Ni in the showerhead 3 configured by a Ni-containing member into the TiN film.

Since the TiCl₄ gas, which is a raw material gas containing Ti and Cl, and the NH₃ gas as a N-containing reactant gas are supplied from the gas supply mechanism 5 to the showerhead 3 as a Ni-containing member, the following reactions represented by Equations (1) and (2) occur on the showerhead 3.

$$T i C {l}_{4} + N {H}_{3} \to T i N + H C l \qquad ( 1 )$$

$$N i + N C l \to N i C {l}_{2} ( g ) ↑ + {H}_{2} \qquad ( 2 )$$

Further, NiCl₂, which is a Ni compound, in Equation (2) is introduced into the TiN film by the following reaction represented by Equation (3).

$$T i C {l}_{4} + N {H}_{3} + N i C {l}_{2} \to T i N i N + H C l \qquad ( 3 )$$

The reactions described above proceed easily when a temperature of the showerhead 3 falls within the above-described range of 150 degrees C. to 600 degrees C., for example, 450 degrees C.

At this time, a Ni concentration in the TiN film may be in a range of 2 at % to 10 at %, and specifically within a range of 2.5 at % to 5 at %.

As described above, according to the present embodiment, Ni is incorporated into the TiN film, and preferentially precipitates at the N-sites or the grain boundaries of TiN. Thus, even when a gas containing Ti and Cl is used as the Ti raw material gas, an increase in specific resistance and inhibition of crystal grain growth due to Cl are suppressed. Therefore, it is possible to form a TiN film having a low resistance.

Hereinafter, effects of incorporating Ni into the TiN film according to the present embodiment will be described based on experimental examples.

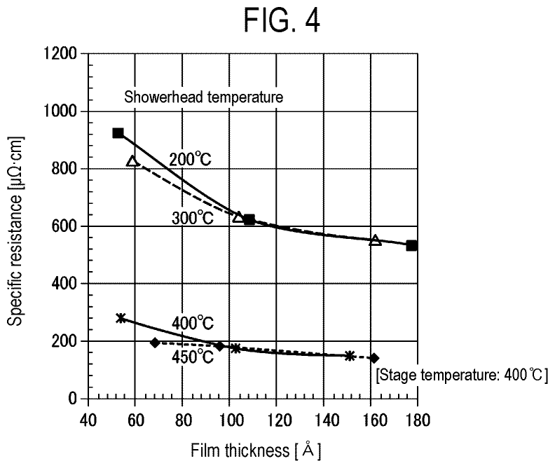

FIG. 4 is a diagram illustrating a relationship between a film thickness and a specific resistance of a TiN film, which is formed by ALD while varying a showerhead temperature in a range between 200 degrees C. and 450 degrees C. Here, a stage temperature was set to 400 degrees C., and an ALD cycle time was set to 1.1 seconds (standard condition (ST)). As a result of measuring a Ni concentration in the film at this time by Rutherford backscattering Spectrometry (RBS) analysis, the Ni concentration was approximately 0 at % at the showerhead temperature of 200 degrees C., and approximately 4 at % at the showerhead temperature of 450 degrees C.

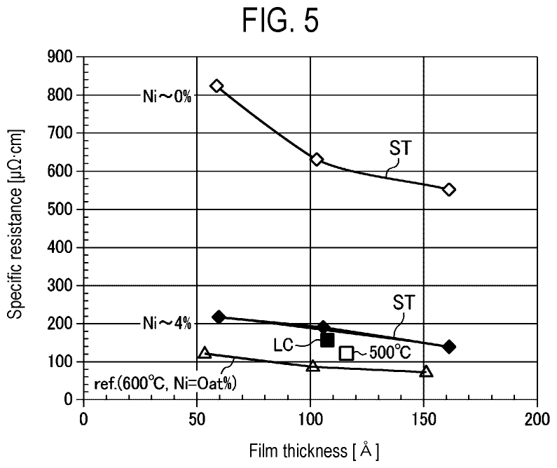

FIG. 5 is a diagram illustrating a relationship between a film thickness and a specific resistance of a TiN film, which is formed with a Ni concentration of approximately 0 at % and with the Ni concentration of approximately 4 at %. Here, in addition to the above-mentioned standard condition, a case (long cycle: LC) in which the stage temperature was set to 400 degrees C. and the ALD cycle time was lengthened to 12 seconds, and a case in which the stage temperature was set to 500 degrees C. are also illustrated with respect to the Ni concentration of approximately 4 at %. Further, for comparison, a case (ref.), in which a film was formed without incorporating Ni and the stage temperature was set to 600 degrees C., is also illustrated.

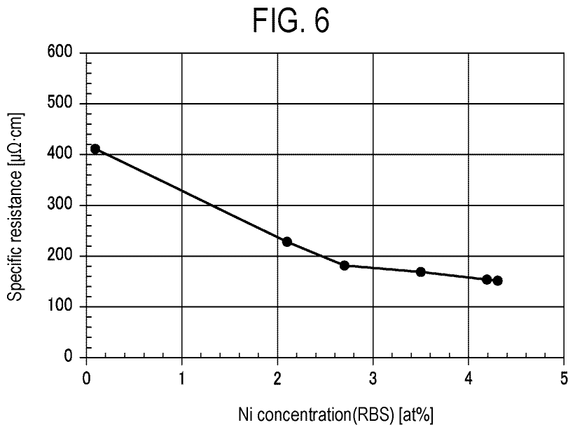

FIG. 6 is a diagram illustrating a relationship between a Ni concentration measured by RBS and a specific resistance of a TiN film having a film thickness of 100 angstroms (10 nm), when the Ni concentration in the film was varied by adjusting the showerhead temperature and others.

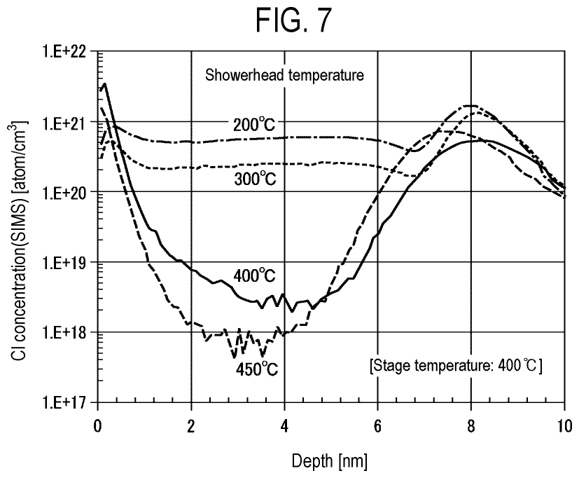

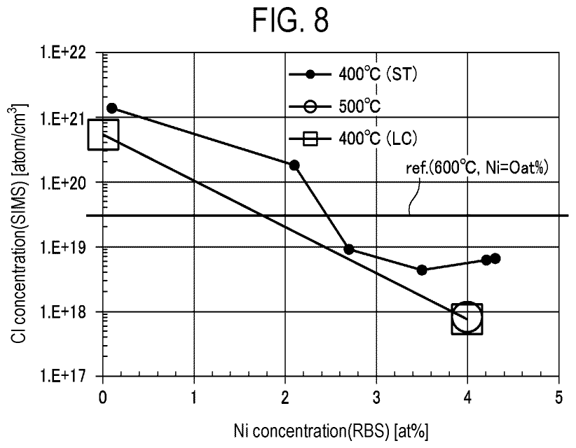

FIG. 7 is a diagram illustrating a concentration distribution of Cl in a TiN film, which is formed by ALD while varying a showerhead temperature in a range between 200 degrees C. and 450 degrees C. and setting a stage temperature to 400 degrees C., similar to FIG. 4. Further, FIG. 8 is a diagram illustrating a relationship between a Ni concentration measured by RBS and a Cl concentration measured by secondary ion mass spectrometry (SIMS) in a TiN film. In FIG. 8, a stage temperature was 400 degrees C. and 500 degrees C., and in the case of 400 degrees C., both the standard condition (ST) and the long cycle (LC) were applied. Further, a Cl concentration in a case where a film was formed at the stage temperature of 600 degrees C. without incorporating Ni is illustrated for comparison (ref.).

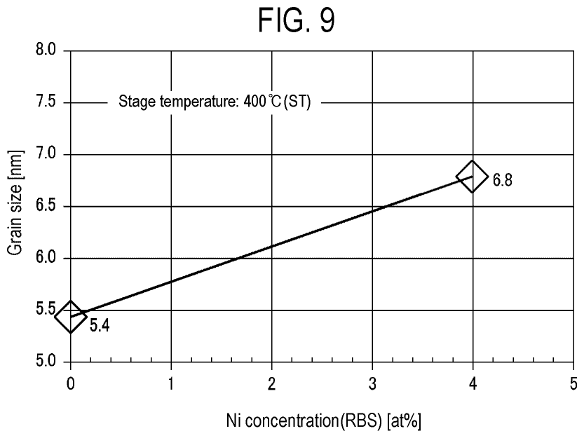

FIG. 9 is a diagram illustrating a relationship between a Ni concentration and a grain size of a TiN film. Here, film formation was performed under the standard condition (ST) with the stage temperature set to 400 degrees C., and the grain size was measured by X-ray diffraction (XRD).

From these drawings, it can be recognized that by increasing a showerhead temperature, Ni can be incorporated into a TiN film being formed, which in turn reduces a specific resistance of the TiN film (see FIGS. 4 and 5). Further, it can be recognized that when Ni is incorporated, a TiN film having a low specific resistance is obtained even at a low stage temperature of 400 degrees C., and the specific resistance can be further reduced by lengthening the ALD cycle time or increasing the stage temperature to 500 degrees C. (see FIG. 5). Furthermore, it can be recognized that the specific resistance is significantly reduced with the Ni concentration of 2 at % or higher, particularly 2.5 at % or higher (2.5 at % to 5 at %) (see FIG. 6). Moreover, as illustrated in FIGS. 6 to 8, the Cl concentration decreases as the showerhead temperature increases (see FIG. 7), and as the Ni concentration in the TiN film increases, the grain size increases while the Cl concentration decreases (see FIGS. 8 and 9). These results may support the fact that a specific resistance of a TiN film is reduced by incorporating Ni into the film to decrease a Cl concentration in the film and increase a grain size.

In addition, since the film formation condition was not necessarily optimized in the above experimental examples, the specific resistances of the films formed by incorporating Ni (at 400 degrees C. and 500 degrees C.) were higher than that of the comparative case (ref.) in which the film is formed at 600 degrees C. without incorporating Ni (see FIG. 5). However, it is expected that by optimizing the film formation condition while incorporating Ni, a TiN film is formed to have an ultra-low Cl concentration and a larger grain size than conventional cases, and it is expected that even at a low temperature of approximately 400 degrees C., a TiN film having a resistance lower than approximately 100 micro-ohms centimeters, which may be obtained in conventional cases of forming a TiN film at 600 degrees C., is obtained. Further, it is expected that by performing high-temperature film formation at approximately 600 degrees C. while incorporating Ni into the film, a TiN film having a further reduced resistance is obtained due to a further reduced CI concentration and a further enlarged grain size.

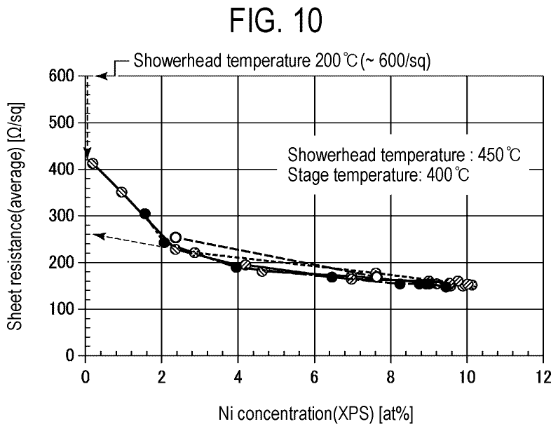

FIG. 10 is a diagram illustrating a relationship between a Ni concentration measured by XPS and a sheet resistance Rs [ohms/sq] of a TiN film, which is formed at the showerhead temperature of 450 degrees C. and the stage temperature of 400 degrees C. while varying the Ni concentration. The sheet resistance Rs at the Ni concentration of 0 at % was 400 [ohms/sq], which is lower than 600 [ohms/sq] at the showerhead temperature of 200 degrees C., but this reduction in the sheet resistance was due to an increase in the showerhead temperature. Further, the sheet resistance Rs rapidly decreased when the Ni concentration becomes 2 at % or higher, and remained low up to 10 at %. Thus, it was confirmed that the low resistance is obtained at least in the Ni concentration ranging from 2 a % to 10 at %.

In addition, as in the present embodiment, in the case of incorporating Ni from the showerhead 3 configured as a Ni-containing member into the TiN film, an amount of Ni incorporated into the film tends to decrease, when the film formation is repeated and a thickness of deposits adhered to the surface of the showerhead becomes equal to or higher than a certain thickness. This issue can be addressed by a countermeasure such as adjusting a maintenance cycle.

### Second Embodiment

Next, a second embodiment as a specific embodiment will be described.

In the second embodiment, Ni is incorporated into a TiN film by introducing an operation of supplying a Ni raw material gas that contains Ni into a step of forming the TiN film by an ALD method.

### Film Forming Apparatus

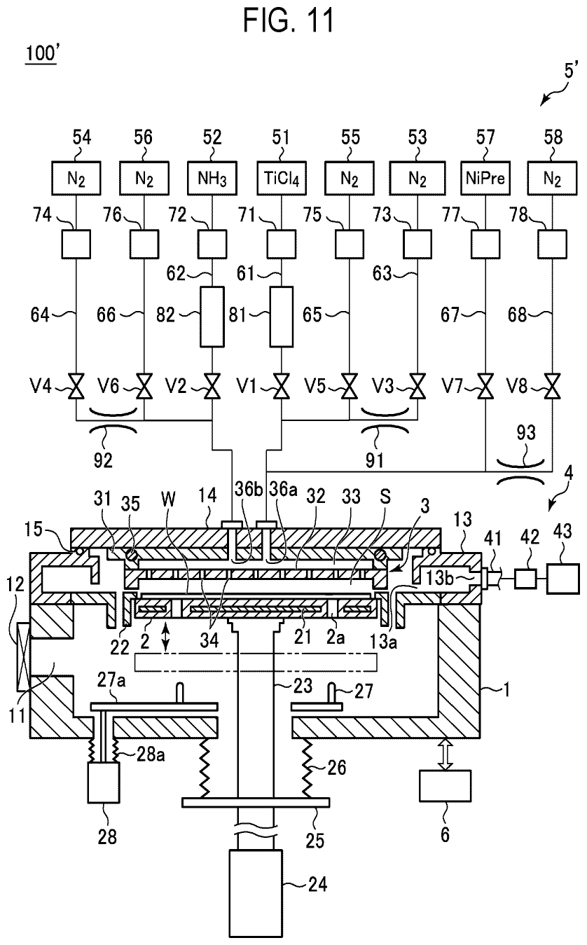

FIG. 11 is a cross-sectional view illustrating an example of a film forming apparatus for use in performing a film forming method according to a second embodiment.

As illustrated in FIG. 11, a film forming apparatus 100′ is configured similarly to the film forming apparatus 100 in FIG. 1, except that the film forming apparatus 100′ includes a gas supply mechanism 5′ having a different configuration from the gas supply mechanism 5 in FIG. 1. Accordingly, components other than the gas supply mechanism 5′ in FIG. 11 are denoted by the same reference numerals as those in FIG. 1 and descriptions thereof will be omitted.

The gas supply mechanism 5′ further includes, compared to the gas supply mechanism 5 in FIG. 1, a Ni raw material gas source (NiPre) 57 that supplies a Ni raw material gas (Ni precursor) and a fifth N₂ gas source 58. Further, the present embodiment also describes an example in which TiCl₄ gas, which is a gas containing Ti and Cl, is used as a Ti-containing raw material gas, NH₃ gas is used as a N-containing reactant gas, and N₂ gas is used as a purge gas or a carrier gas. However, in the present embodiment, the Ti-containing raw material gas is not particularly limited. The Ti-containing raw material gas is not limited to a gas containing Cl, and may also be a gas that does not contain Cl, such as tetrakis(dimethylamino)titanium (TDMAT) or tetrakis(diethylamino)titanium (TDEAT).

A Ni raw material gas line 67 is connected to the Ni raw material gas source 57. In the Ni raw material gas line 67, a valve V7 is attached on a downstream side and a flow rate controller 77 is attached on an upstream side. The Ni raw material gas (Ni precursor) is supplied from the Ni raw material gas source 57. As the Ni raw material gas, (EtCp)₂Ni and (C₃H₅) (C₅H₅) Ni may be used. The Ni raw material gas line 67 is connected to a downstream side of a joining point where the first N₂ gas line 63 joins the TiCl₄ gas line 61.

A fifth N₂ gas line 68 is connected to the fifth N₂ gas source 58. In the fifth N₂ gas line 68, a valve V8 is attached on a downstream side and a flow rate controller 78 is attached on an upstream side. The fifth N₂ gas line 68 is connected to a downstream side of the valve V7 in the Ni raw material gas line 67. The N₂ gas supplied from the fifth N₂ gas source 58 via the fifth N₂ gas line 68 functions as a purge gas and as a carrier gas for the Ni raw material gas. The N₂ gas from the fifth N₂ gas source 58 is continuously supplied during film formation. In addition, an orifice 93 for preventing backflow is provided on a downstream side of the valve V8 in the fifth N₂ gas line 68.

### Film Forming Method

Next, an example of a film forming method performed using the film forming apparatus 100′ configured as described above will be described.

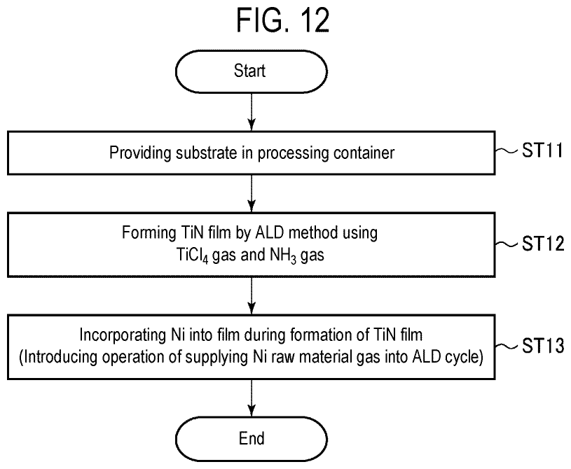

FIG. 12 is a flowchart illustrating an example of a film forming method according to the second embodiment. First, the substrate W is provided in the processing container 1 to set state in which film formation can be performed (step ST11). This step is performed in the same manner as step ST1 of the first embodiment.

Subsequently, a TiN film is formed by an ALD method (step ST12). This step is also performed basically in the same manner as step ST2 of the first embodiment. That is, a sequence including operation S1 of supplying TiCl₄ gas, operation S2 of performing purging, operation S3 of supplying NH₃ gas, and operation S4 of performing purging is performed a predetermined number of times.

During the TiN film formation by the ALD method in step ST12 described above, Ni is incorporated into the film (step ST13). In the present embodiment, step ST13 may be performed by introducing an operation of supplying a Ni raw material gas into the ALD cycle of step ST12.

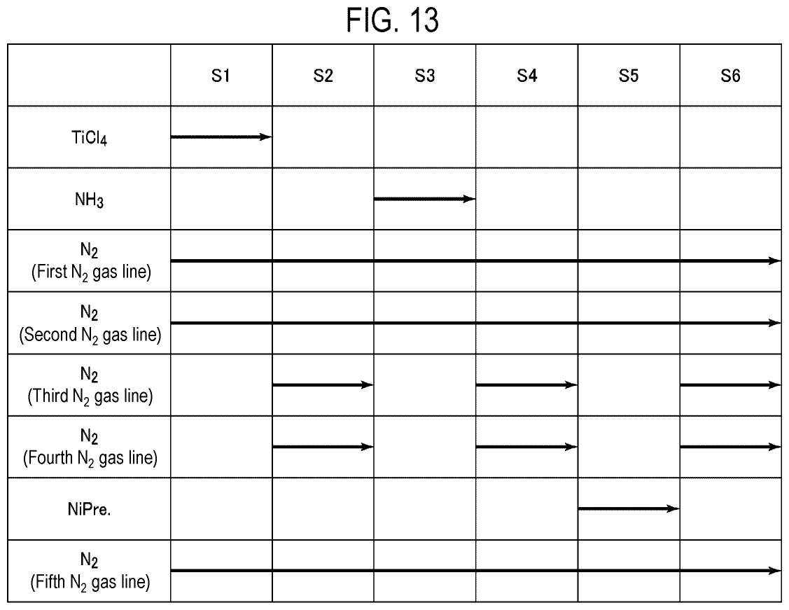

FIG. 13 is a diagram illustrating an example of a gas supply sequence in an ALD cycle in which an operation of supplying a Ni raw material gas is introduced into step ST12. Here, the following sequence is performed in a state in which the valves V3, V4, and V8 are continuously kept open to continuously supply N2 gas from the first N₂ gas source 53, the second N₂ gas source 54, and the fifth N₂ gas source 58. That is, similarly to step ST2 of the first embodiment, the following operations S5 and S6 are performed after forming a unit TiN film by operation S1 of supplying the TiCl₄ gas, operation S2 of performing the purging, operation S3 of supplying the NH₃ gas, and operation S4 of performing the purging. In operation S5, the valve V7 is opened to supply the Ni raw material gas into the processing space S. In operation S6, the valve V7 is closed, and purging is performed to remove residual gases on the substrate W in a state in which only the N₂ gas is supplied into the processing space S. At this time, the valves V5 and V6 may be opened to enhance the purging by supplying the N₂ gas as a purge gas from the third N₂ gas line 65 and the fourth N₂ gas line 66. The sequence of operations S1 to S6 is performed a predetermined number of times. Thus, Ni is incorporated into the film during the TiN film formation of step ST12, and a Ni-containing TiN film having a desired film thickness is formed. In addition, the supply of Ni raw material gas in step ST13 may not be necessarily performed in every ALD cycle of the TiN film formation in step ST12, as long as the TiN film formation includes the sequence of operations S1 to S6. For example, the Ni raw material gas may be supplied after repeating the ALD cycle of the TiN film formation a desired number of times.

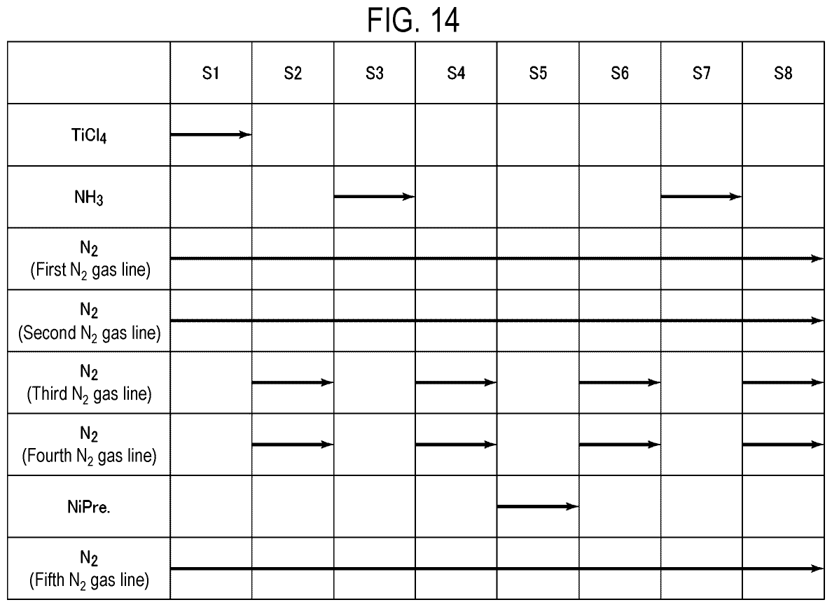

FIG. 14 is a diagram illustrating another example of a gas supply sequence in an ALD cycle in which an operation of supplying a Ni raw material gas is introduced into step ST12. Here, as in the example of FIG. 13, operations S7 and S8 are performed after performing operations S1 to S6. In operation S7, the valve V2 is opened to supply the NH₃ gas into the processing space S. In operation S8, the valve V2 is closed, purging is performed to remove residual gases on the substrate W in a state in which only the N₂ gas is supplied into the processing space S. That is, operation S7 is a process of nitriding the Ni raw material gas adsorbed on the surface of the substrate. At this time, the valves V5 and V6 may be opened to enhance the purging by supplying the N₂ gas as a purge gas from the third N₂ gas line 65 and the fourth N₂ gas line 66. The sequence of operations S1 to S8 is performed a predetermined number of times. Thus, Ni is incorporated into the film during the TiN film formation of step ST12, and a Ni-containing TiN film having a desired film thickness is formed. In addition, in this example as well, the supply of Ni raw material gas in step ST13 may not be necessarily performed in every ALD cycle of the TiN film formation in step ST12, as long as the TiN film formation includes the sequence of operations S1 to S8. For example, the Ni raw material gas may be supplied after repeating the ALD cycle of the TiN film formation a desired number of times. Further, although the showerhead 3 in the present embodiment has the same configuration as in the first embodiment, the showerhead 3 is not limited to a Ni-containing member, and may be made of another material such as Al. Furthermore, the showerhead 3 may also have a configuration in which the heater 35 is not provided.

In the present embodiment as well, since Ni is incorporated into the TiN film, Ni preferentially precipitates at N-sites or grain boundaries of TiN. Thus, elements that increase a resistance of TiN are suppressed from entering the N-sites or the grain boundaries of TiN, and elements that inhibit crystal growth are suppressed from precipitating at the grain boundaries. Therefore, the resistance of the TiN film can be further reduced.

### Other Applications

Although the embodiments have been described above, the embodiments disclosed herein should be considered to be exemplary and not restrictive in all respects. The above embodiments may be omitted, replaced, or modified in various ways without departing from the scope and spirit of the appended claims.

For example, the method of incorporating Ni into the film during the TiN film formation by ALD is not limited to the method described in the above embodiments, and various other methods may be adopted. For example, although a showerhead was used as a Ni-containing member in the first embodiment, the present disclosure is not limited thereto, and another Ni-containing member, which is disposed to be brought into contact with a raw material gas containing Ti and Cl and a N-containing reactant gas for TiN film formation, may be used.

In addition, the film forming apparatuses illustrated in FIGS. 1 and 11 are merely examples, and a structure of an apparatus is not limited as long as the apparatus may perform ALD film formation.

According to the present disclosure, a film forming method and a film forming apparatus capable of forming a titanium nitride film with a further reduced resistance.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
providing a substrate in a processing container;
forming a titanium nitride film on the substrate by an atomic layer deposition (ALD) method by supplying a titanium-containing raw material gas and a nitrogen-containing reactant gas into the processing container; and
incorporating nickel into the titanium nitride film during the forming the titanium nitride film.

2. The film forming method of claim 1, wherein the incorporating the nickel into the titanium nitride film includes incorporating nickel in a nickel-containing member, which is provided in the processing container at a position where the nickel-containing member is brought into contact with the raw material gas and the reactant gas, into the titanium nitride film.

3. The film forming method of claim 2, wherein the nickel is incorporated into the titanium nitride film by a reaction of a nickel compound, which is generated by a reaction of the nickel-containing member with the raw material gas and the reactant gas, with the titanium nitride film on the substrate.

4. The film forming method of claim 3, wherein the nickel-containing member is a showerhead that introduces the raw material gas and the reactant gas into the processing container.

5. The film forming method of claim 4, wherein a temperature of the showerhead is set to 150 degrees C. to 600 degrees C. when performing the incorporating the nickel into the titanium nitride film.

6. The film forming method of claim 1, wherein the incorporating the nickel into the titanium nitride film is performed by introducing an operation of supplying a nickel raw material gas that contains nickel into the forming the titanium nitride film by the ALD method.

7. The film forming method of claim 6, wherein the nickel raw material gas is (EtCp)₂Ni or (C₃H₅) (C₅H₅)Ni.

8. The film forming method of claim 6, wherein the forming the titanium nitride film by the ALD method and the incorporating the nickel into the titanium nitride film are performed by a process including a sequence which includes: an operation of supplying the titanium-containing raw material gas into the processing container in which the substrate is provided; an operation of purging a residual gas from the processing container; an operation of supplying the nitrogen-containing reactant gas into the processing container; an operation of purging a residual gas from the processing container; an operation of supplying the nickel raw material gas into the processing container; and an operation of purging a residual gas from the processing container.

9. The film forming method of claim 6, wherein the forming the titanium nitride film by the ALD method and the incorporating the nickel into the titanium nitride film are performed by a process including a sequence which includes: an operation of supplying the titanium-containing raw material gas into the processing container in which the substrate is provided; an operation of purging a residual gas from the processing container; an operation of supplying the nitrogen-containing reactant gas into the processing container; an operation of purging a residual gas from the processing container; an operation of supplying the nickel raw material gas into the processing container; an operation of purging a residual gas from the processing container; an operation of supplying the nitrogen-containing reactant gas into the processing container; and an operation of purging a residual gas from the processing container.

10. The film forming method of claim 1, wherein the incorporating the nickel into the titanium nitride film includes incorporating nickel into the titanium nitride film so that a concentration of nickel in the titanium nitride film falls within a range of 2 at % to 10 at %.

11. The film forming method of claim 10, wherein the incorporating the nickel into the titanium nitride film includes incorporating the nickel into the titanium nitride film so that the concentration of nickel in the titanium nitride film falls within a range of 2.5 at % to 5 at %.

12. The film forming method of claim 11, wherein the titanium-containing raw material gas is a raw material gas containing titanium and chlorine.

13. The film forming method of claim 12, wherein the raw material gas containing titanium and chlorine is TiCl₄ gas, and the nitrogen-containing reactant gas is NH₃ gas.

14. The film forming method of claim 13, wherein the forming the titanium nitride film is performed in a state in which a temperature of the substrate falls within a range of 300 degrees C. to 600 degrees C.

15. The film forming method of claim 1, wherein the titanium-containing raw material gas is a raw material gas containing titanium and chlorine.

16. A film forming apparatus comprising:
a processing container in which a substrate is accommodated;
a gas supply mechanism configured to supply at least a titanium-containing raw material gas and a nitrogen-containing reactant gas into the processing container;
an exhaust mechanism configured to exhaust the processing container;
a heating mechanism configured to heat the substrate;
a nickel-containing material supply configured to supply a nickel-containing material to the substrate; and
a controller,
wherein the controller controls the gas supply mechanism, the exhaust mechanism, the heating mechanism, and the nickel-containing material supply to execute:
providing the substrate in the processing container;
forming a titanium nitride film on the substrate by an atomic layer deposition (ALD) method by supplying the titanium-containing raw material gas and the nitrogen-containing reactant gas into the processing container; and
incorporating nickel into the titanium nitride film by the nickel-containing material supply during the forming the titanium nitride film.

17. The film forming apparatus of claim 16, wherein the nickel-containing material supply includes a nickel-containing member, which is disposed in the processing container at a position where the nickel-containing member is brought into contact with the raw material gas and the reactant gas, and
wherein the incorporating the nickel into the titanium nitride film includes incorporating nickel in the nickel-containing member into the titanium nitride film.

18. The film forming apparatus of claim 16, wherein the nickel-containing material supply includes a mechanism configured to supply a nickel raw material gas that contains nickel into the processing container, and
wherein the incorporating the nickel into the titanium nitride film is performed by introducing an operation of supplying the nickel raw material gas into the forming the titanium nitride film by the ALD method.

19. The film forming apparatus of claim 18, wherein the titanium-containing raw material gas contains titanium and chlorine.

20. The film forming apparatus of claim 16, wherein the titanium-containing raw material gas contains titanium and chlorine.
